(19) United States
(12) Patent Application Publication
(10) Pub. No.: US 2022/0254823 A1
(43) Pub. Date: Aug. 11, 2022

(54) IMAGING DEVICE

(71) Applicant: SONY SEMICONDUCTOR SOLUTIONS CORPORATION, KANAGAWA (JP)

(72) Inventor: HIROSHI TAKAHASHI, TOKYO (JP)

(21) Appl. No.: 17/597,532

(22) PCT Filed: Jul. 10, 2020
(86) PCT No.: PCT/JP2020/027066

§ 371 Date: Jan. 10, 2022

(30) Foreign Application Priority Data
Jul. 19, 2019 (JP) 2019-133347

(51) Int. Cl. H01L 27/146

(52) U.S. Cl. CPC H01L 27/14614; H01L 27/1462; H01L 27/14643

(57) ABSTRACT

An imaging device according to an embodiment of the present disclosure includes: a photoelectric converter that is provided on an inner side than one principal surface of a semiconductor substrate; a transfer gate electrode that includes a first electrode section and a second electrode section, and provides as a transfer path which reads electric charge that has been photoelectrically converted by the photoelectric converter, the first electrode section extending, in a columnar shape, from the one principal surface of the semiconductor substrate in a depth direction of the semiconductor substrate, the second electrode section further extending, in a columnar shape, from the first electrode section in the depth direction; and a first conduction-type region that includes a first conduction-type impurity and is provided on a lateral part of the transfer gate electrode. A width of the second electrode section in at least one direction in a plane of the one principal surface is smaller than a width of the first electrode section in the at least one direction. The first conduction-type region is provided at least in a region of an under part of the first electrode section and a lateral part of the second electrode section, in the at least one direction.

### TECHNICAL FIELD

The present disclosure relates to an imaging device.

### BACKGROUND ART

In a CMOS (Complementary Metal-Oxide-Semiconductor) imaging device, it has been proposed to further enlarge an area of a photoelectric converter by stacking the photoelectric converter and a transfer transistor in a depth direction of a semiconductor substrate (see, for example, PTL 1). Such a structure of the transfer transistor is also referred to as vertical gate structure. The vertical gate structure enables a gate electrode extending in the depth direction from one principal surface of the semiconductor substrate to read electric charge from the photoelectric converter disposed inside the semiconductor substrate.

### CITATION LIST

### Patent Literature

PTL 1: Japanese Unexamined Patent Application Publication No. 2005-223084

### SUMMARY OF THE INVENTION

In such a vertical gate structure, it is desired that a size of the photoelectric converter be ensured while advancing the miniaturization of a pixel size by further optimizing the structure.

Accordingly, it is desirable to provide an imaging device having a more optimized vertical gate structure.

An imaging device according to an embodiment of the present disclosure includes: a photoelectric converter that is provided on an inner side than one principal surface of a semiconductor substrate; a transfer gate electrode that includes a first electrode section and a second electrode section, and provides as a transfer path which reads electric charge that has been photoelectrically converted by the photoelectric converter, the first electrode section extending, in a columnar shape, from the one principal surface of the semiconductor substrate in a depth direction of the semiconductor substrate, the second electrode section further extending, in a columnar shape, from the first electrode section in the depth direction; and a first conduction-type region that includes a first conduction-type impurity and is provided on a lateral part of the transfer gate electrode. A width of the second electrode section in at least one direction in a plane of the one principal surface is smaller than a width of the first electrode section in the at least one direction. The first conduction-type region is provided at least in a region of an under part of the first electrode section and a lateral part of the second electrode section, in the at least one direction.

In the imaging device according to the embodiment of the present disclosure, the transfer gate electrode is provided by forming the first electrode section and the second electrode section separately. This makes it possible to make a shape of the transfer gate electrode more complex, for example. Thus, it is possible to form a first conduction-type region serving as a transfer path of electric charge in a more complex region.

### BRIEF DESCRIPTION OF DRAWINGS

FIG. 1 is an overall schematic configuration diagram of an imaging device according to a first embodiment of the present disclosure.

FIG. 2 is an equivalent circuit diagram illustrating electrical coupling of components of a sensor pixel 2 according to the embodiment.

FIG. 3 is a schematic view of a planar arrangement of the components in a case where the sensor pixel 2 according to the embodiment is viewed planarly from one principal surface of a semiconductor substrate 11.

FIG. 4 is a schematical vertical cross-sectional view of a vertical gate structure of a transfer transistor TR according to the embodiment.

FIG. 5 is a schematical vertical cross-sectional view of a vertical gate structure of a transfer transistor according to a comparative example.

FIG. 6 is a vertical cross-sectional view of a step of a method of forming the vertical gate structure of the transfer transistor according to the comparative example.

FIG. 7 is a vertical cross-sectional view of a step of the method of forming the vertical gate structure of the transfer transistor according to the comparative example.

FIG. 8 is a vertical cross-sectional view of a specific cross-sectional shape of a transfer gate electrode TG according to the embodiment.

FIG. 9A is a plan view and a cross-sectional view illustrating a correspondence between a variation of a planar shape of the transfer gate electrode TG according to the embodiment and a cross-sectional shape thereof.

FIG. 9B is a plan view and a cross-sectional view illustrating a correspondence between a variation of the planar shape of the transfer gate electrode TG according to the embodiment and a cross-sectional shape thereof.

FIG. 9C is a plan view and a cross-sectional view illustrating a correspondence between a variation of the planar shape of the transfer gate electrode TG according to the embodiment and a cross-sectional shape thereof.

FIG. 10 is a vertical cross-sectional view of one of sequential processes of forming the transfer transistor TR according to the embodiment.

FIG. 11 is a vertical cross-sectional view of one of the sequential processes of forming the transfer transistor TR according to the embodiment.

FIG. 12 is a vertical cross-sectional view of one of the sequential processes of forming the transfer transistor TR according to the embodiment.

FIG. 13 is a vertical cross-sectional view of one of the sequential processes of forming the transfer transistor TR according to the embodiment.

FIG. 14 is a vertical cross-sectional view of one of the sequential processes of forming the transfer transistor TR according to the embodiment.

FIG. 15 is a vertical cross-sectional view of one of the sequential processes of forming the transfer transistor TR according to the embodiment.

FIG. 16 is a vertical cross-sectional view of one of the sequential processes of forming the transfer transistor TR according to the embodiment.

FIG. 17 is a vertical cross-sectional view of one of the sequential processes of forming the transfer transistor TR according to the embodiment.

FIG. 18 is a vertical cross-sectional view of one of sequential processes of forming a transfer transistor according to a first modification example.

FIG. 19 is a vertical cross-sectional view of one of the sequential processes of forming the transfer transistor according to the first modification example.

FIG. 20 is a vertical cross-sectional view of one of the sequential processes of forming the transfer transistor according to the first modification example.

FIG. 21 is a vertical cross-sectional view of one of the sequential processes of forming the transfer transistor according to the first modification example.

FIG. 22 is a vertical cross-sectional view of one of the sequential processes of forming the transfer transistor according to the first modification example.

FIG. 23 is a vertical cross-sectional view of one of sequential processes of forming a transfer transistor according to a second modification example.

FIG. 24 is a vertical cross-sectional view of one of the sequential processes of forming the transfer transistor according to the second modification example.

FIG. 25 is a vertical cross-sectional view of one of the sequential processes of forming the transfer transistor according to the second modification example.

FIG. 26 is a vertical cross-sectional view of one of the sequential processes of forming the transfer transistor according to the second modification example.

FIG. 27 is a vertical cross-sectional view of one of the sequential processes of forming the transfer transistor according to the second modification example.

FIG. 28 is a vertical cross-sectional view of one of sequential processes of forming a transfer transistor according to a third modification example.

FIG. 29 is a vertical cross-sectional view of one of the sequential processes of forming the transfer transistor according to the third modification example.

FIG. 30 is a vertical cross-sectional view of one of the sequential processes of forming the transfer transistor according to the third modification example.

FIG. 31 is a vertical cross-sectional view of one of the sequential processes of forming the transfer transistor according to the third modification example.

FIG. 32 is a vertical cross-sectional view of one of the sequential processes of forming the transfer transistor according to the third modification example.

FIG. 33 is a schematic plan view and a schematical vertical cross-sectional view of a vertical gate structure of a transfer transistor tr according to a second embodiment of the present disclosure.

FIG. 34A is a schematic plan view of a variation of: planar shapes of a first electrode section 111 and a second electrode section 112 according to the embodiment; and a positional relationship between the first electrode section 111 and the second electrode section 112.

FIG. 34B is a schematic plan view of a variation of: planar shapes of the first electrode section 111 and the second electrode section 112 according to the embodiment; and a positional relationship between the first electrode section 111 and the second electrode section 112.

FIG. 34C is a schematic plan view of a variation of: planar shapes of the first electrode section 111 and the second electrode section 112 according to the embodiment; and a positional relationship between the first electrode section 111 and the second electrode section 112.

FIG. 35 is a vertical cross-sectional view of one of sequential processes of forming the transfer transistor tr according to the embodiment.

FIG. 36 is a vertical cross-sectional view of one of the sequential processes of forming the transfer transistor tr according to the embodiment.

FIG. 37 is a vertical cross-sectional view of one of the sequential processes of forming the transfer transistor tr according to the embodiment.

FIG. 38 is a vertical cross-sectional view of one of the sequential processes of forming the transfer transistor tr according to the embodiment.

FIG. 39 is a diagram illustrating an example of a schematic configuration of an imaging system 100 including an imaging device 1 according to the embodiments and the modification examples thereof of the present disclosure.

FIG. 40 is an example of a flowchart of imaging operation performed by the imaging system 100.

FIG. 41 is a block diagram depicting an example of schematic configuration of a vehicle control system.

FIG. 42 is a diagram of assistance in explaining an example of installation positions of an outside-vehicle information detecting section and an imaging section.

FIG. 43 is a view depicting an example of a schematic configuration of an endoscopic surgery system.

FIG. 44 is a block diagram depicting an example of a functional configuration of a camera head and a camera control unit (CCU).

### MODES FOR CARRYING OUT THE INVENTION

The following describes embodiments of the present disclosure in detail with reference to the drawings. The following description is a specific example of the present disclosure, but the present disclosure is not limited to the following embodiments. In addition, the present disclosure is not limited to arrangement, dimensions, dimensional ratios, and the like of the constituent elements illustrated in the drawings.

It is to be noted that description is given in the following order.

### 1. First Embodiment

1.1. Overall Configuration of Imaging Device

1.2. Configuration of Transfer Transistor

1.3. Method of Forming Transfer Transistor

1.4. Modification Examples

### 2. Second Embodiment

2.1. Configuration of Transfer Transistor

2.2. Method of Forming Transfer Transistor

### 3. Application Examples

### 1. FIRST EMBODIMENT

### 1.1. Overall Configuration of Imaging Device

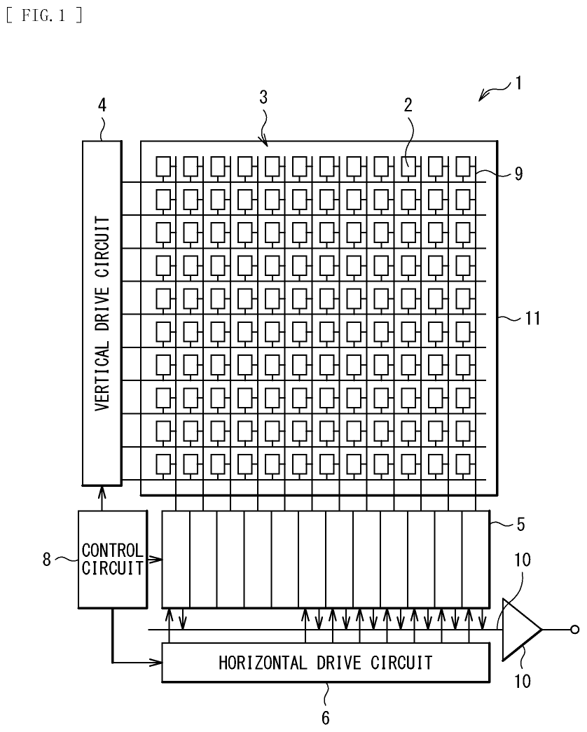

First, with reference to FIG. 1, an overall configuration of an imaging device according to a first embodiment of the present disclosure will be described. FIG. 1 is an overall schematic configuration diagram of the imaging device according to the present embodiment.

As illustrated in FIG. 1, an imaging device 1 includes, for example: a pixel region 3 including a plurality of sensor pixels 2 arranged on a semiconductor substrate 11 such as a silicon substrate; a vertical drive circuit 4; a column signal processing circuit 5; a horizontal drive circuit 6; an output circuit 7; and a control circuit 8. The imaging device 1 is, for example, a CMOS (Complementary Metal-Oxide-Semiconductor) imaging device.

The sensor pixel 2 includes: a photoelectric converter including a photodiode and the like; and a pixel circuit that converts electric charge read from the photoelectric converter into a pixel signal. The photoelectric converters are disposed on the semiconductor substrate 11 in a two-dimensional arrangement in a matrix, to convert incident light into electric charge. The pixel circuit includes, for example, a transfer transistor, a floating diffusion, an amplifier transistor, and a reset transistor. The pixel circuit converts the electric charge read from the photoelectric converter into the pixel signal. The pixel circuit may further include a selection transistor.

The photoelectric converter and the pixel circuit included in the sensor pixel 2 may be provided on one semiconductor substrate, or may be provided separately on two semiconductor substrates. For example, in a case where the photoelectric converter and the pixel circuit are provided separately on the two separate semiconductor substrates: the photoelectric converter, the transfer transistor, and the floating diffusion may be provided on a first semiconductor substrate; and the amplifier transistor, the reset transistor, and the selection transistor may be provided on a second semiconductor substrate.

The control circuit 8 generates a clock signal, a control signal, and the like on the basis of a master clock. The clock signal serves as a reference for operation of the vertical drive circuit 4, the column signal processing circuit 5, the horizontal drive circuit 6, and the like. The control circuit 8 supplies the generated clock signal and the generated control signal to each of the vertical drive circuit 4, the column signal processing circuit 5, and the horizontal drive circuit 6.

The vertical drive circuit 4 includes, for example, a shift register, and selects each sensor pixel 2 provided in the pixel region 3 while sequentially scanning the sensor pixels 2 in units of rows. Thereafter, the vertical drive circuit 4 supplies the pixel signal generated in each sensor pixel 2 to the column signal processing circuit 5 via a vertical signal line.

The column signal processing circuit 5 is disposed, for example, for each column of sensor pixels 2 (i.e., for each vertical signal line), and converts the pixel signal outputted for each column from each sensor pixel 2 from an analog signal to a digital signal. At this time, the column signal processing circuit 5 may further perform signal processing such as noise reduction or signal amplification on the pixel signal outputted from the sensor pixel 2.

The horizontal drive circuit 6 includes, for example, a shift register. The horizontal drive circuit 6 sequentially outputs horizontal scan pulses, and sequentially selects the column signal processing circuits 5, thereby causing each column signal processing circuit 5 to output the pixel signal to a horizontal signal line 10. It is to be noted that, for example, an unillustrated horizontal selection switch may be provided between the column signal processing circuit 5 and the horizontal signal line 10.

The output circuit 7 performs signal processing on the pixel signals sequentially supplied, through the horizontal signal line 10, from the respective column signal processing circuits 5. Thereafter, the output circuit 7 outputs the pixel signals subjected to the signal processing as imaging data.

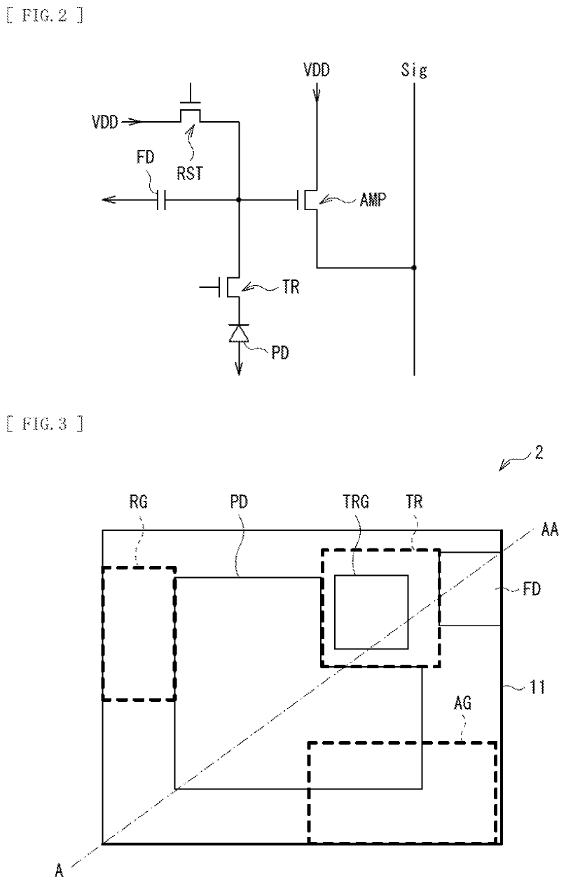

Subsequently, referring to FIGS. 2 and 3, a configuration of the sensor pixel 2 will be described. FIG. 2 is an equivalent circuit diagram illustrating electrical coupling of components of the sensor pixel 2, and FIG. 3 is a schematic view of a planar arrangement of the components in a case where the sensor pixel 2 is viewed planarly from one principal surface of the semiconductor substrate 11.

As illustrated in FIG. 2, for example, the sensor pixel 2 includes: a photoelectric converter PD; and the pixel circuit including a transfer transistor TR, a floating diffusion FD, an amplifier transistor AMP, and a reset transistor RST.

The photoelectric converter PD including a photodiode and the like generates, by photoelectrically converting the incident light, electric charge corresponding to an amount of received light. The photoelectric converter PD is electrically coupled to a source of the transfer transistor TR, and the electric charge photoelectrically converted by the photoelectric converter PD is transferred to the floating diffusion FD when the transfer transistor TR is turned on.

The floating diffusion FD accumulates the electric charge photoelectrically converted by the photoelectric converter PD. Further, an electric potential of the floating diffusion FD varies depending on the accumulated electric charge. Thus, the amplifier transistor AMP whose gate is electrically coupled to the floating diffusion FD is able to output a signal corresponding to the electric potential of the floating diffusion FD to a signal line Sig. The reset transistor RST electrically couples the floating diffusion FD and the power supply line VDD with each other. The reset transistor RST is turned on to discharge the electric charge accumulated in the floating diffusion FD to the power supply line VDD.

The photoelectric converter PD, the floating diffusion FD, and respective gate electrodes of the transfer transistor TR, the amplifier transistor AMP, and the reset transistor RST may be disposed, for example, as illustrated in FIG. 3.

Specifically, the photoelectric converter PD is disposed in such a manner as to be embedded inside the semiconductor substrate 11 at a substantially central portion of the sensor pixel 2. A transfer gate electrode TG of the transfer transistor TR is disposed over the semiconductor substrate 11 with a gate insulation film interposed therebetween, on an edge of a region in which the photoelectric converter PD is disposed. Further, the floating diffusion FD is disposed as, for example, an n+-type impurity region on the semiconductor substrate 11 in a region adjacent to the transfer gate electrode TG of the transfer transistor TR.

A gate electrode AG of the amplifier transistor AMP and a gate electrode RG of the reset transistor RST are each disposed over the semiconductor substrate 11 with the gate insulation film interposed therebetween, on an edge of the sensor pixel 2. It is to be noted that a portion of the gate electrode AG of the amplifier transistor AMP and a portion of the gate electrode RG of the reset transistor RST may each be disposed over the semiconductor substrate 11 in a region in which the photoelectric converter PD is disposed.

In the imaging device 1, the photoelectric converter PD is disposed inside semiconductor substrate 11, thus, it is possible to form the pixel circuit including the amplifier transistor AMP, the reset transistor RST, and the like on one principal surface of the semiconductor substrate 11 in the region in which the photoelectric converter PD is disposed. Further, in the imaging device 1, the transfer gate electrode TG of the transfer transistor TR is formed in such a manner as to be extended in a depth direction of the semiconductor substrate 11. This makes it possible for the transfer transistor TR to transfer the electric charge from the photoelectric converter PD disposed inside the semiconductor substrate 11 to the floating diffusion FD disposed on the one principal surface of the semiconductor substrate 11. Such a structure of a field-effect transistor is also referred to as a vertical gate structure.

A technology according to the present embodiment relates to the transfer transistor TR having the vertical gate structure. The technology according to the present embodiment enables a transfer path of the electric charge to be formed in a more appropriate region by providing the transfer gate electrode TG of the transfer transistor TR in such a manner as to be gradually reduced in size in the depth direction of the semiconductor substrate 11. Further, according to the technology of the present embodiment, it is also possible to form the transfer gate electrode TG of the transfer transistor TR more easily.

### 1.2. Configuration of Transfer Transistor

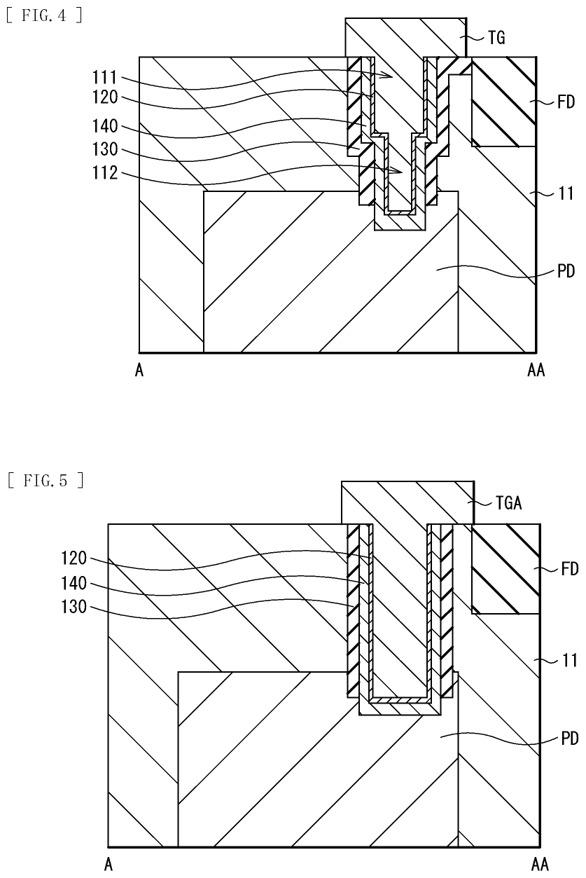

Hereinafter, referring to FIGS. 4 to 9C, the vertical gate structure of the transfer transistor TR according to the present embodiment will be described in more detail. FIG. 4 is a schematical vertical cross-sectional view of the vertical gate structure of the transfer transistor TR according to the present embodiment. The cross-sectional view of FIG. 4 is, for example, a cross-sectional view taken along a line A-AA of the sensor pixel 2 illustrated in FIG. 3.

As illustrated in FIG. 4, in the sensor pixel 2, the photoelectric converter PD is disposed inside the semiconductor substrate 11, and the floating diffusion FD is disposed on a one principal surface-side of the semiconductor substrate 11.

The semiconductor substrate 11 is, for example, a substrate including a semiconductor such as silicon. Specifically, the semiconductor substrate 11 may be a silicon substrate into which a second conduction-type impurity (e.g., a p-type impurity such as boron (B) or aluminum (Al)) has been introduced.

The photoelectric converter PD has a p-n junction and is a photodiode that converts incident light into electric charge. The photoelectric converter PD may be provided, for example, by forming a region in which a first conduction-type impurity is introduced and a region in which the second conduction-type impurity is introduced inside the semiconductor substrate 11 of a second conduction type, and forming the p-n junction.

The floating diffusion FD is a region that accumulates the electric charge transferred from the photoelectric converter PD. The floating diffusion FD may be provided, for example, by introducing the first conduction-type impurity (e.g., an n-type impurity such as phosphorus (P) or arsenic (As)) into the semiconductor substrate 11 at a high concentration. It is to be noted that the “high concentration” described above indicates that the concentration of the first conduction-type impurity is high compared with a region other than the floating diffusion FD where the first conduction-type impurity is introduced.

The transfer gate electrode TG is provided in such a manner as to extend in the depth direction of the semiconductor substrate 11 from the one principal surface of the semiconductor substrate 11 to the photoelectric converter PD. Specifically, the transfer gate electrode TG includes: a first electrode section 111 extending, in a columnar shape, from the one principal surface-side of the semiconductor substrate 11 in the depth direction of the semiconductor substrate 11; and a second electrode section 112 extending, in a columnar shape, from the first electrode section in the depth direction of the semiconductor substrate 11.

Further, the second electrode section 112 is provided in such a manner that a width of the second electrode section 112 in at least one direction in the plane of the one principal surface of the semiconductor substrate 11 is smaller than a width of the first electrode section 111 in the same direction. According to this, the transfer gate electrode TG is provided in such a manner as to be gradually reduced in size in the depth direction of the semiconductor substrate 11. It is to be noted that, regarding the widths in a direction other than the one direction in the plane of the one principal surface of the semiconductor substrate 11, the width of the second electrode section 112 may be the same as the width of the first electrode section 111.

For example, the second electrode section 112 may be provided in a region included in a region in which the first electrode section 111 is formed, in a planar view of the one principal surface of the semiconductor substrate 11. Specifically, the second electrode section 112 may be provided in a region which is smaller than the region in which the first electrode section 111 is formed and which is on an inner side than the region in which the first electrode section 111 is formed, in a planar view of the one principal surface of the semiconductor substrate 11. According to this, the transfer gate electrode TG is provided in such a manner as to be gradually reduced in size in the depth direction of the semiconductor substrate 11.

The transfer gate electrode TG comes into contact with the semiconductor substrate 11 with a gate insulation film 120 interposed therebetween. The semiconductor substrate 11 on a side of the transfer gate electrode TG is provided with a first conduction-type region 130 into which the first conduction-type impurity has been introduced. As a result, a predetermined electric potential is applied to the transfer gate electrode TG, which increases the electric potential of the first conduction-type region 130. Thus, the electric charge accumulated in the photoelectric converter PD is transferred from the photoelectric converter PD to the floating diffusion FD via the first conduction-type region 130. In other words, the first conduction-type region 130 functions as a transfer path of the electric charge from the photoelectric converter PD to the floating diffusion FD.

The transfer gate electrode TG may be formed by using, for example, a polysilicon conductive material. Further, the gate insulation film 120 may be formed by using a silicon oxide film provided by oxidizing a surface of the polysilicon included in the transfer gate electrode TG or the silicon included in the semiconductor substrate 11.

The first conduction-type region 130 is provided by introducing the first conduction-type impurity (e.g., the n-type impurity such as phosphorus (P) or arsenic (As)) into the semiconductor substrate 11 to an under part of the first electrode section 111 and to a lateral part of the second electrode section 112, in at least one direction in the plane of the one principal surface of the semiconductor substrate 11. Specifically, the first conduction-type region 130 may be provided continuously along an outer shape of the transfer gate electrode TG, from the lateral part of the second electrode section 112 to a lateral part of the first electrode section 111, in at least one direction in the plane of the one principal surface of the semiconductor substrate 11. In this case, the first conduction-type region 130 is provided in such a manner as to bend in the depth direction of the semiconductor substrate 11, along the lateral part of the second electrode section 112, the under part of the first electrode section 111 protruding from the second electrode section 112, and the lateral part of the first electrode section 111. The first conduction-type region 130 is provided along the outer shape of the transfer gate electrode TG, which makes it possible to control a region in which the first conduction-type region 130 is provided by controlling the shape of the transfer gate electrode TG.

Further, a second conduction-type region 140 into which the second conduction-type impurity has been introduced may be provided to the semiconductor substrate 11 between the transfer gate electrode TG and the first conduction-type region 130. Specifically, the second conduction-type region 140 may be formed by introducing the second conduction-type impurity (for example, the p-type impurity such as boron (B) or aluminum (Al)) into a region including an interface of the semiconductor substrate 11 opposing the transfer gate electrode TG. For example, the second conduction-type region 140 may be provided continuously to the semiconductor substrate 11 along an under part of the second electrode section 112, the lateral part of the second electrode section 112, the under part of the first electrode section 111 protruding from the second electrode section 112, and the lateral part of the first electrode section 111.

The second conduction-type region 140 is able to suppress generation of a dark current caused by defects and the like present on a side surface and a bottom surface of the transfer gate electrode TG, thereby suppressing generation of a defect such as a white scratch in the sensor pixel 2. Accordingly, the second conduction-type region 140 is preferably provided on the side surface of the transfer gate electrode TG with respect to any direction in the plane of the one principal surface of the semiconductor substrate 11 in such a manner as to cover the first electrode section 111 and the second electrode section 112.

As described above, the transfer gate electrode TG includes the first electrode section 111 and the second electrode section 112, thereby being able to flexibly change the shape in the depth direction of the semiconductor substrate 11. Accordingly, the transfer gate electrode TG is able to provide more flexibly a course of the transfer path from the photoelectric converter PD to the floating diffusion FD.

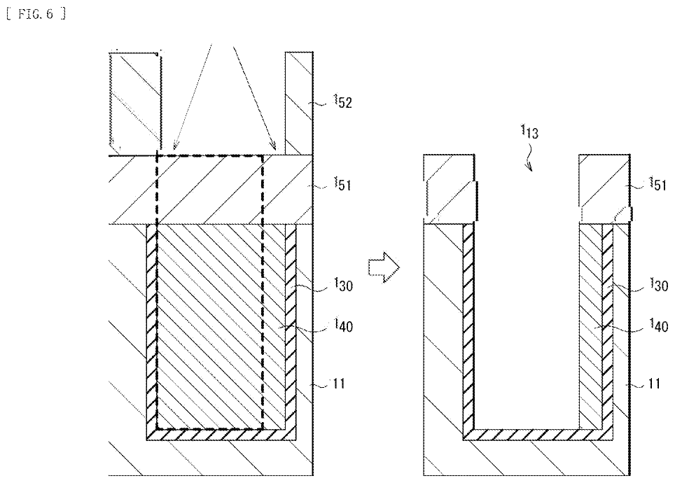

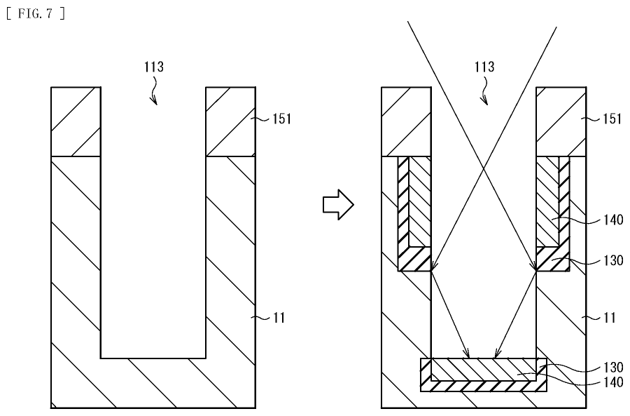

Here, referring to FIGS. 5 to 7, effects achieved by the transfer gate electrode TG of the transfer transistor TR according to the present embodiment will be described in more detail. FIG. 5 is a schematical vertical cross-sectional view of a vertical gate structure of a transfer transistor according to a comparative example. FIGS. 6 and 7 are each a vertical cross-sectional view of a step of a method of forming the vertical gate structure of the transfer transistor according to the comparative example.

As illustrated in FIG. 5, a transfer gate electrode TGA according to the comparative example is provided in such a manner as to extend in the depth direction from the one principal surface-side of the semiconductor substrate 11. The transfer gate electrode TGA according to the comparative example differs from the transfer gate electrode TG according to the present embodiment in that a width of the transfer gate electrode TGA is constant in the depth direction of the semiconductor substrate 11. For this reason, in the comparative example, the first conduction-type region 130 is provided without being bent in the depth direction of the semiconductor substrate 11.

As illustrated in FIG. 6, for example, the transfer transistor according to comparative example may be formed by: forming the first conduction-type region 130 and the second conduction-type region 140 on the semiconductor substrate 11; and thereafter causing the semiconductor substrate 11 to have an opening 113 in which a transfer gate electrode TGA is to be provided.

Specifically, as illustrated in FIG. 6, first, the first conduction-type region 130 is formed by introducing the first conduction-type impurity into the semiconductor substrate 11 on which a hard mask 151 is stacked. Thereafter, the second conduction-type impurity is further introduced into the semiconductor substrate 11 by using a patterning resist 152, thereby forming the second conduction-type region 140. Thereafter, the semiconductor substrate 11 is etched, thereby causing the semiconductor substrate 11 to have the opening 113 in which the transfer gate electrode TGA is to be provided.

However, in such a method of forming the transfer gate electrode TGA, there may be a case where a position of patterning of the resist used in introducing the second conduction-type impurity does not completely coincide with a position of patterning of the resist used in etching. In such a case, the opening 113 may not necessarily be formed in a desired region with respect to the first conduction-type region 130 or the second conduction-type region 140. For example, if the center of the first conduction-type region 130 or the second conduction-type region 140 does not coincide with the center of the opening 113, distributions of the first conduction-type region 130 and the second conduction-type region 140 will be unbalanced on both sides of the opening 113.

Accordingly, in the method of forming the first conduction-type region 130 and the second conduction-type region 140 on the semiconductor substrate 11 and thereafter causing the semiconductor substrate 11 to have the opening 113, it is difficult to form the first conduction-type region 130 and the second conduction-type region 140 on the lateral part of the transfer gate electrode TGA at desired distributions.

Further, as illustrated in FIG. 7, for example, the transfer transistor according to the comparative example may be formed by: causing the semiconductor substrate 11 to have the opening 113 in which the transfer gate electrode TGA is to be provided; and thereafter forming the first conduction-type region 130 and the second conduction-type region 140 on the semiconductor substrate 11.

Specifically, as illustrated in FIG. 7, first, the semiconductor substrate 11 on which the hard mask 151 is stacked is etched to cause the semiconductor substrate 11 to have the opening 113 in which the transfer gate electrode TGA is to be provided. Thereafter, the first conduction-type impurity and the second conduction-type impurity are ion-implanted into the opening 113 in an oblique direction, whereby the first conduction-type region 130 and the second conduction-type region 140 may be formed over the side surface and the bottom surface of the inside of the opening 113.

However, in a case where an aspect ratio of the opening 113 is high, the ion-implantation in such a direction in forming the transfer gate electrode TGA makes it difficult to ion-implant the conduction-type impurities into the side surface in a deep portion of the opening 113. Further, in a case where the conduction-type impurities are ion-implanted more obliquely in order to introduce more conduction-type impurities into the inside of the opening 113, the introduced conduction-type impurities are reflected on the side surface of the opening 113. This causes the conduction-type impurities to be introduced into the bottom surface of the opening 113 at an amount that is more than an assumed amount.

Thus, in the method of causing the semiconductor substrate 11 to have the opening 113 and thereafter forming the first conduction-type region 130 and the second conduction-type region 140 on the semiconductor substrate 11, it is difficult to control concentrations of the conduction-type impurities of the first conduction-type region 130 and the second conduction-type region 140 in the lateral part of the deep portion of the transfer gate electrode TGA.

In the transfer transistor TR according to the present embodiment, the portion of the transfer gate electrode TG extending in the depth direction of the semiconductor substrate 11 is provided by forming the first electrode section 111 and the second electrode section 112 separately. Accordingly, in the transfer transistor TR of the present embodiment, it is possible to form the first conduction-type region 130 separately onto the lateral part of the first electrode section 111 and the lateral part of the second electrode section 112 correspondingly to the first electrode section 111 and the second electrode section 112. This makes it possible, in the transfer transistor TR according to the present embodiment, to form the first conduction-type region 130 in a desired region more easily.

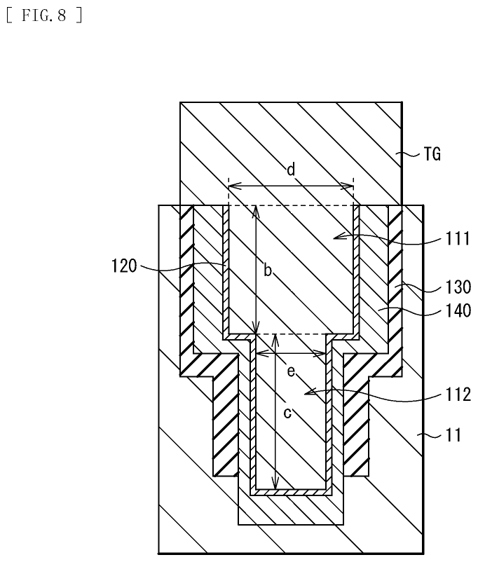

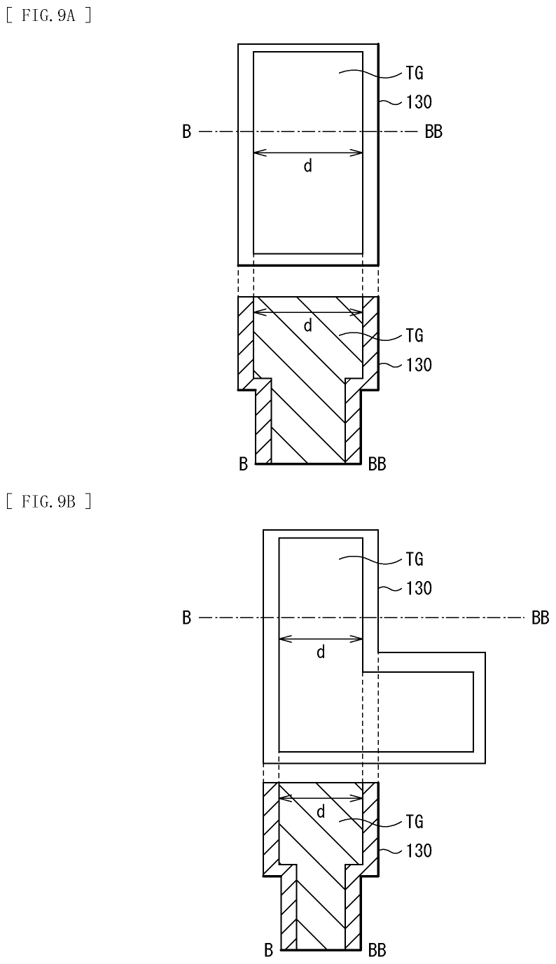

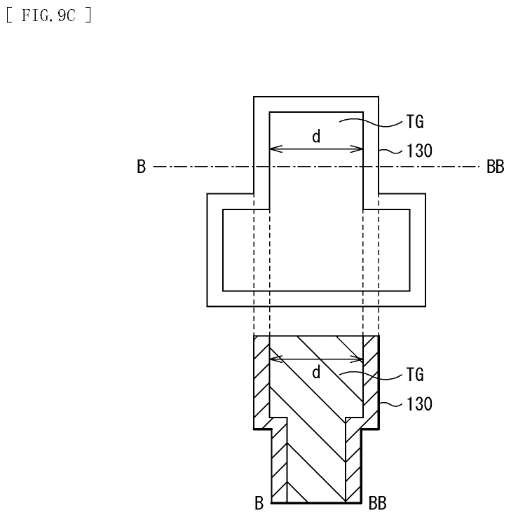

Subsequently, referring to FIGS. 8 to 9C, specific shapes of the transfer gate electrode TG of the transfer transistor TR according to the present embodiment will be described. FIG. 8 is a vertical cross-sectional view of a specific cross-sectional shape of the transfer gate electrode TG. FIGS. 9A to 9C are each a plan view and a cross-sectional view illustrating a correspondence between a variation of a planar shape of the transfer gate electrode TG and a cross-sectional shape thereof. It is to be noted that, in each of FIGS. 9A to 9C, the cross-sectional view of the lower drawing is a cross section taken along a line B-BB in the upper drawing.

As illustrated in FIG. 8, dimensions of the cross-sectional shape of the transfer gate electrode TG in a predetermined direction in the plane of the one principal surface of the semiconductor substrate 11 are defined as follows. Specifically, a length (forming depth) of the first electrode section 111 in the depth direction of the semiconductor substrate 11 is represented by b, a length (forming depth) of the second electrode section 112 in the depth direction of the semiconductor substrate 11 is represented by c, a width of the first electrode section 111 in a predetermined direction in the plane of the one principal surface of the semiconductor substrate 11 is represented by d, and a width of the second electrode section 112 in the predetermined direction in the plane of the one principal surface of the semiconductor substrate 11 is represented by e.

It is preferable that the transfer gate electrode TG be formed to have a cross-sectional shape in which b+c<6d and d>e are satisfied (where 0<b<3.5d and 0<c<3.5d are satisfied). In a case where the transfer gate electrode TG is formed with an aspect ratio in the above ranges, the aspect ratio of the opening may be set to an appropriate value for the etching and the introduction of the conduction-type impurities, upon forming the first electrode section 111, the second electrode section 112, and the first conduction-type region 130. It is therefore easier to form the transfer gate electrode TG and the first conduction-type region 130 in the desired region.

Further, it is more preferable that the transfer gate electrode TG be formed to have a cross-sectional shape in which b+c<2d and d>e are satisfied (where 0<b and 0<c are satisfied). In a case where the transfer gate electrode TG is formed with an aspect ratio in the above ranges, the aspect ratio of the opening may be set to an appropriate value for the etching and the introduction of the conduction-type impurities, upon forming the first electrode section 111, the second electrode section 112, and the first conduction-type region 130. It is therefore further easier to form the transfer gate electrode TG and the first conduction-type region 130 in the desired region.

As illustrated in FIGS. 9A to 9C, the planar shape of the transfer gate electrode TG of the transfer transistor TR according to the present embodiment may be of any shape. Further, in the transfer gate electrode TG, a cross-sectional shape at any one or more cut lines passing through the planar shape of the transfer gate electrode TG may be the cross-sectional shape illustrated in FIG. 4.

For example, as illustrated in FIG. 9A, the planar shape of the transfer gate electrode TG may be a rectangular shape. In this case, the cross-sectional shape of the transfer gate electrode TG illustrated in FIG. 4 may be a cross-sectional shape in which the rectangular shape is cut along a cutting line that is parallel to the short side.

For example, as illustrated in FIG. 9B, the planar shape of the transfer gate electrode TG may be a bent hook shape (i.e., L shape). In this case, the cross-sectional shape of the transfer gate electrode TG illustrated in FIG. 4 may be a cross-sectional shape in which the hook shape is cut along a cutting line that is parallel to the shortest side.

For example, as illustrated in FIG. 9C, the planar shape of the transfer gate electrode TG may be a shape in which a smaller rectangular shape protrudes from the long side of a rectangular shape. In this case, the cross-sectional shape of the transfer gate electrode TG illustrated in FIG. 4 may be a cross-sectional shape in which the protruding rectangular shape is cut along a cutting line perpendicular to a protruding direction.

Further, although not illustrated, the planar shape of the transfer gate electrode TG may include a curve in the outer shape. For example, the planar shape of the transfer gate electrode TG may be a circular shape, an elliptical shape, or a shape obtained by replacing the vertices of a polygon with circular arcs. In this case, the cross-sectional shape of the transfer gate electrode TG illustrated in FIG. 4 may be a cross-sectional shape in which the planar shape of the transfer gate electrode TG is cut along any line passing through the planar shape of the transfer gate electrode TG.

### 1.3. Method of Forming Transfer Transistor

Next, referring to FIGS. 10 to 17, a method of forming the transfer transistor TR according to the present embodiment will be described. FIGS. 10 to 17 are vertical cross-sectional views sequentially explaining processes of forming the transfer transistor TR according to the present embodiment.

First, as illustrated in FIG. 10, the hard mask 151 is stacked on the semiconductor substrate 11, and thereafter, the opening 113 having a size corresponding to the first electrode section 111 is etched in the semiconductor substrate 11. Thereafter, the first conduction-type impurity is ion-implanted into the opening 113 in the oblique direction to form the first conduction-type region 131 on a side surface and a bottom surface inside the opening 113. Thereafter, the second conduction-type impurity is ion-implanted into the opening 113 in the oblique direction to form the second conduction-type region 141 on the side surface and the bottom surface inside the opening 113.

Here, the aspect ratio of the opening 113 is selected in such a manner that, for example, when the first conduction-type impurity and the second conduction-type impurity are ion-implanted in the oblique direction, reflected components on the side surface inside the opening 113 are negligible, and the first conduction-type region 131 and the second conduction-type region 141 are formable on the side surface inside the opening 113 at satisfactory concentrations.

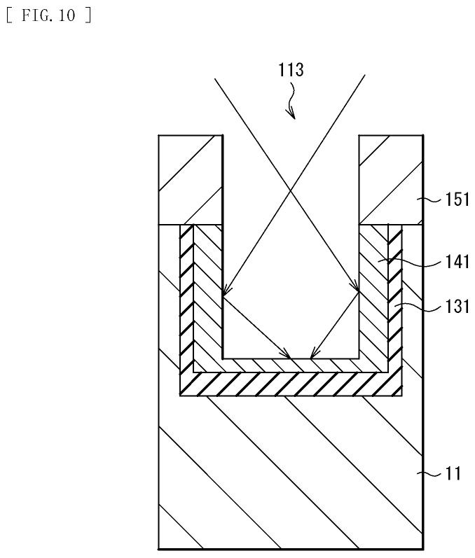

Thereafter, as illustrated in FIG. 11, the first conduction-type impurity is ion-implanted vertically into the bottom surface inside the opening 113 to form a first conduction-type region 132 on the under part of the opening 113.

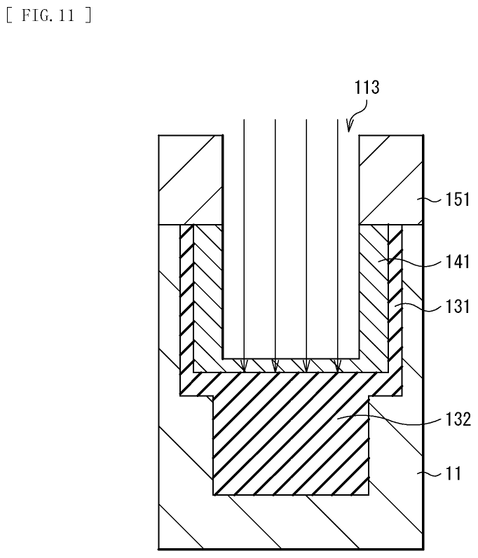

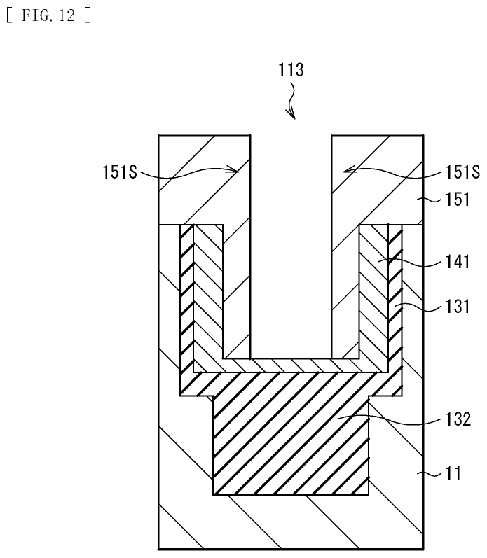

Thereafter, as illustrated in FIG. 12, a side-wall spacer 151S is formed inside the opening 113 to reduce an opening width of the opening 113. In this case, a width of the first conduction-type region 130 provided on the lateral part of the second electrode section 112 may be controlled by controlling a width of the side-wall spacer 151S.

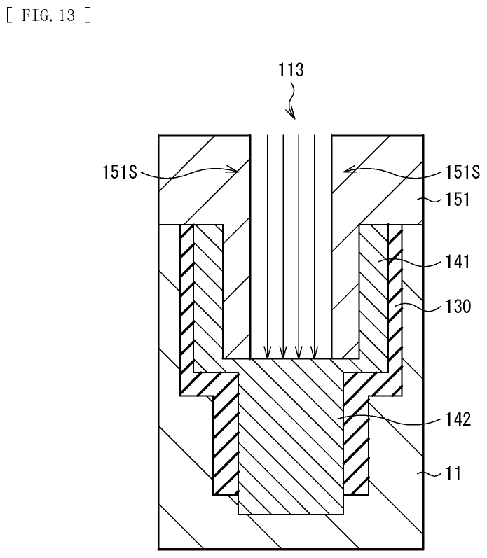

Thereafter, as illustrated in FIG. 13, the second conduction-type impurity is ion-implanted vertically into the bottom surface inside the opening 113 using the hard mask 151 and the side-wall spacer 151S as masks, to form a second conduction-type region 142 on the under part of the opening 113.

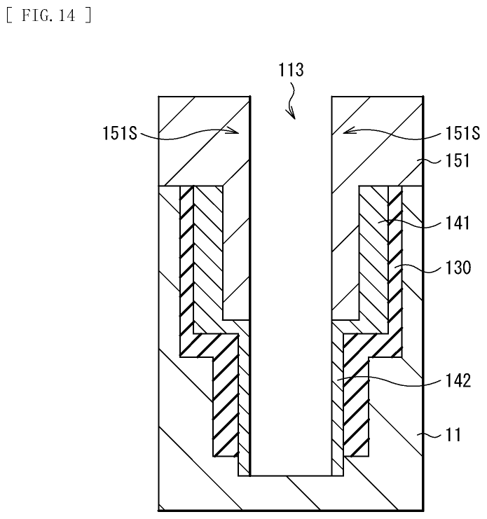

Thereafter, as illustrated in FIG. 14, the bottom surface inside the opening 113 is etched using the hard mask 151 and the side-wall spacer 151S as masks, to extend the opening 113 in the depth direction of the semiconductor substrate 11, thereby causing the semiconductor substrate 11 to have an opening corresponding to the second electrode section 112. The side-wall spacer 151S causes a difference between a region into which the first conduction-type impurity has been introduced and a region into which the second conduction-type impurity has been introduced, which makes it possible to form the first conduction-type region 130 and the second conduction-type region 142 on the lateral part of the second electrode section 112 by the etching illustrated in FIG. 14.

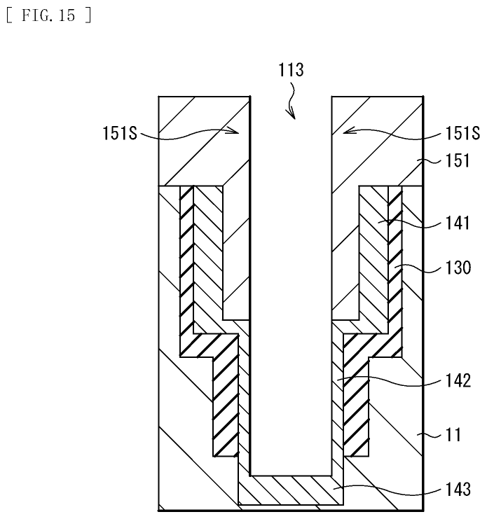

Thereafter, as illustrated in FIG. 15, the second conduction-type impurity is ion-implanted vertically into the bottom surface inside the opening 113 to form a second conduction-type region 143 on the under part of the opening 113.

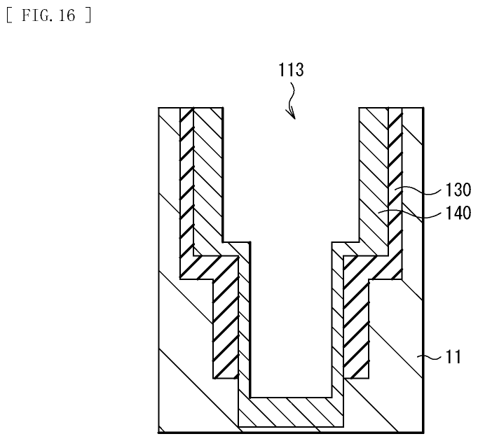

Thereafter, as illustrated in FIG. 16, the hard mask 151 and the side-wall spacer 151S are removed to expose the semiconductor substrate 11 inside the opening 113.

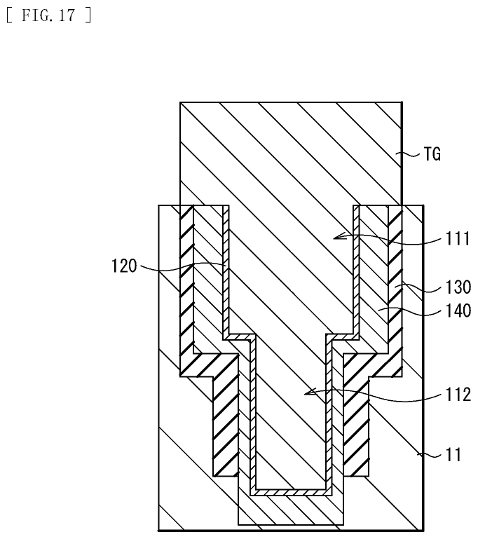

Further, as illustrated in FIG. 17, the gate insulation film 120 and the transfer gate electrode TG are sequentially formed on the semiconductor substrate 11 inside the opening 113. Thus, it is possible to form the transfer gate electrode TG including the first electrode section 111 and the second electrode section 112 on the semiconductor substrate 11. Moreover, it is possible to form the first conduction-type region 130 more easily in the desired region of the lateral part of the transfer gate electrode TG.

Accordingly, the transfer transistor TR according to the present embodiment is able to control the region in which the first conduction-type region 130 is formed with higher accuracy by configuring the transfer gate electrode TG to include the first electrode section 111 and the second electrode section 112. In addition, the transfer transistor TR forms the first conduction-type region 130 by introducing the first conduction-type impurity into the semiconductor substrate 11 a plurality of times. Thus, the transfer transistor TR is able to control the density distribution of the conduction-type impurity in the first conduction-type region 130 with higher accuracy. This makes it possible for the transfer transistor TR according to the present embodiment to transfer more efficiently and stably the electric charge from the photoelectric converter PD from the photoelectric converter PD to the floating diffusion FD.

Further, the transfer gate electrode TG according to the present embodiment is able to control in a self-aligned manner the positional relationship between the first electrode section 111 and the second electrode section 112 by using the side-wall spacer 151S, which makes it possible to further improve accuracy of the shape. In this case, in the transfer gate electrode TG according to the present embodiment, the center (or center of gravity) of the first electrode section 111 and the center (or center of gravity) of the second electrode section 112 substantially coincides with each other, and the planar shape of the first electrode section 111 and the planar shape of the second electrode section 112 are similar to each other.

### 1.4. Modification Examples

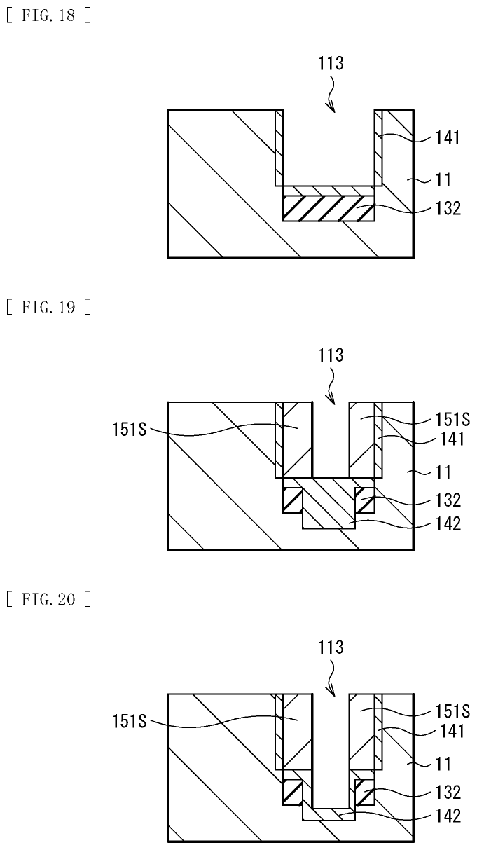

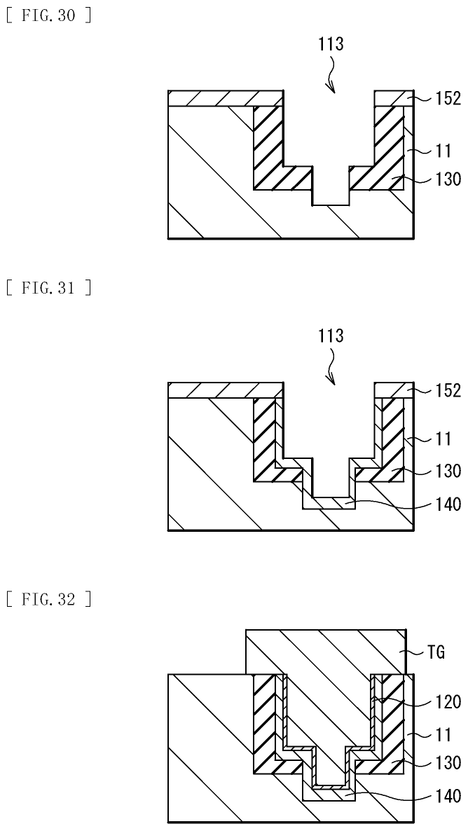

Next, referring to FIGS. 18 to 32, first to third modification examples of the transfer transistor TR according to the present embodiment will be described. Transfer transistors according to the first to third modification examples are formed by methods different from the above-described method of forming the transfer transistor TR, and thus, placements of the first conduction-type region 130 and the second conduction-type region 140 are partially different.

### First Modification Example

Referring to FIGS. 18 to 22, a method of forming a transfer transistor according to the first modification example will be described. FIGS. 18 to 22 are vertical cross-sectional views sequentially explaining processes of forming the transfer transistor according to the first modification example.

In order to pull up more efficiently the electric charge from the photoelectric converter PD disposed inside the semiconductor substrate 11 to the floating diffusion FD disposed on the semiconductor substrate 11, it is conceivable to provide a concentration gradient of the first conduction-type impurity in the depth direction of the semiconductor substrate 11. The transfer transistor according to the first modification example limits a region in which the first conduction-type region 130 is to be formed to the lateral part of the second electrode section 112 and the under part of the first electrode section 111, to thereby increase the concentration gradient of the first conduction-type impurity in the depth direction of the semiconductor substrate 11.

Specifically, as illustrated in FIG. 18, the opening 113 having a size corresponding to the first electrode section 111 is etched in the semiconductor substrate 11. Thereafter, the first conduction-type impurity is ion-implanted vertically into the bottom surface inside the opening 113 to form the first conduction-type region 132 only on the under part of the opening 113. Thereafter, the second conduction-type impurity is ion-implanted into the opening 113 in the oblique direction to form the second conduction-type region 141 on the side surface and the bottom surface inside the opening 113.

Thereafter, as illustrated in FIG. 19, the side-wall spacer 151S is formed inside the opening 113 to reduce the opening width of the opening 113, and the second conduction-type impurity is ion-implanted vertically into the bottom surface inside the opening 113. Thus, the second conduction-type region 142 is formed on the under part of the opening 113.

Thereafter, as illustrated in FIG. 20, the bottom surface inside the opening 113 is etched using the side-wall spacer 151S as a mask, to extend the opening 113 in the depth direction of the semiconductor substrate 11, thereby causing the semiconductor substrate 11 to have an opening corresponding to the second electrode section 112. In this case, an etch depth of the opening 113 is controlled in such a manner that the second conduction-type region 142 remains on the semiconductor substrate 11 of the under part of the opening 113.

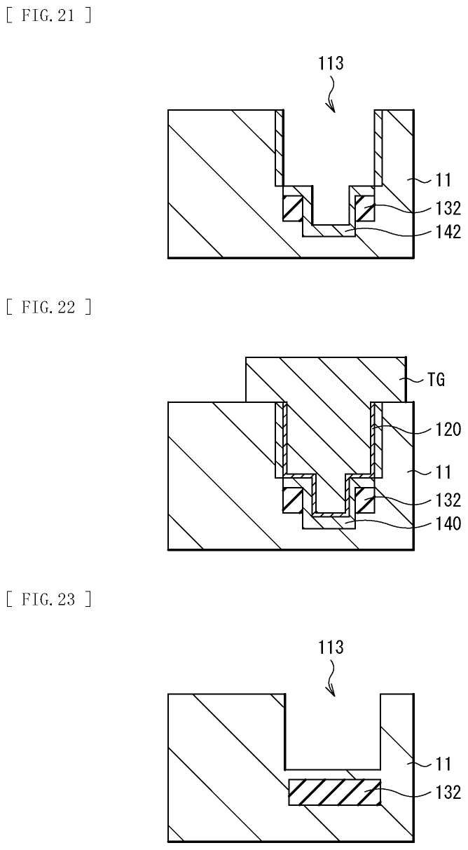

Thereafter, as illustrated in FIG. 21, the hard mask 151 and the side-wall spacer 151S are removed to expose the semiconductor substrate 11 inside the opening 113.

Thereafter, as illustrated in FIG. 22, the gate insulation film 120 and the transfer gate electrode TG are sequentially formed on the semiconductor substrate 11 inside the opening 113. Thus, it is possible to form the transfer transistor according to the first modification example. In the transfer transistor according to the first modification example, the first conduction-type region 132 is formed only on the lateral part of the second electrode section 112 and the under part of the first electrode section 111, and it is thus possible to increase the density gradient of the first conduction-type impurity in the depth direction of the semiconductor substrate 11.

### Second Modification Example

Referring to FIGS. 23 to 27, a method of forming a transfer transistor according to the second modification example will be described. FIGS. 23 to 27 are vertical cross-sectional views sequentially explaining processes of forming the transfer transistor according to the second modification example.

In a similar manner as the transfer transistor according to the first modification example, the transfer transistor according to the second modification example limits a region in which the first conduction-type region 130 is to be formed to the lateral part of the second electrode section 112 and the under part of the first electrode section 111, to thereby increase the concentration gradient of the first conduction-type impurity in the depth direction of the semiconductor substrate 11. Further, in the transfer transistor according to the second modification example, the second conduction-type region 140 is formed by solid phase diffusion or plasma doping.

Specifically, as illustrated in FIG. 23, the opening 113 having a size corresponding to the first electrode section 111 is etched in the semiconductor substrate 11. Thereafter, the first conduction-type impurity is ion-implanted vertically into the bottom surface inside the opening 113 to form the first conduction-type region 132 only on the under part of the opening 113.

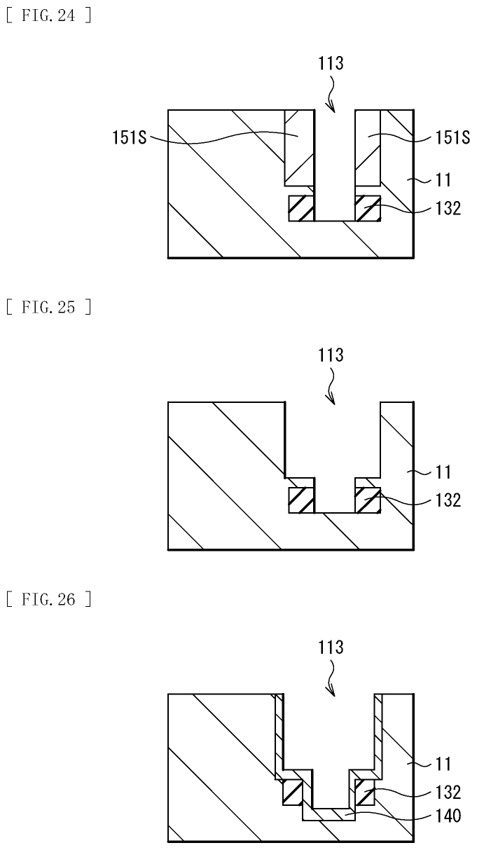

Thereafter, as illustrated in FIG. 24, the side-wall spacer 151S is formed inside the opening 113 to reduce the opening width of the opening 113, and the bottom surface inside the opening 113 is etched using the side-wall spacer 151S as a mask. Thus, the opening 113 is extended in the depth direction of the semiconductor substrate 11, thereby causing the semiconductor substrate 11 to have an opening corresponding to the second electrode section 112. In this case, the opening 113 is etched to a depth that separates the first conduction-type region 132 provided on the under part of the opening 113 in the preceding stage.

Thereafter, as illustrated in FIG. 25, the side-wall spacer 151S is removed to expose the semiconductor substrate 11 inside the opening 113.

Thereafter, as illustrated in FIG. 26, the second conduction-type region 140 is formed uniformly on the surface of the semiconductor substrate 11 exposed by the opening 113, by solid phase diffusion or plasma doping. In a case of using the solid phase diffusion, for example, a layer including the second conduction-type impurity is stacked on the surface of the semiconductor substrate 11 exposed by the opening 113, following which RTA (Rapid Thermal Annealing) is performed, thereby forming the second conduction-type region 140 on the surface of the semiconductor substrate 11. In a case of using the plasma doping, for example, a plasma is generated using gas including the second conduction-type impurity, following which a bias-voltage is applied to the semiconductor substrate 11, thereby forming the second conduction-type region 140 on the surface of the semiconductor substrate 11.

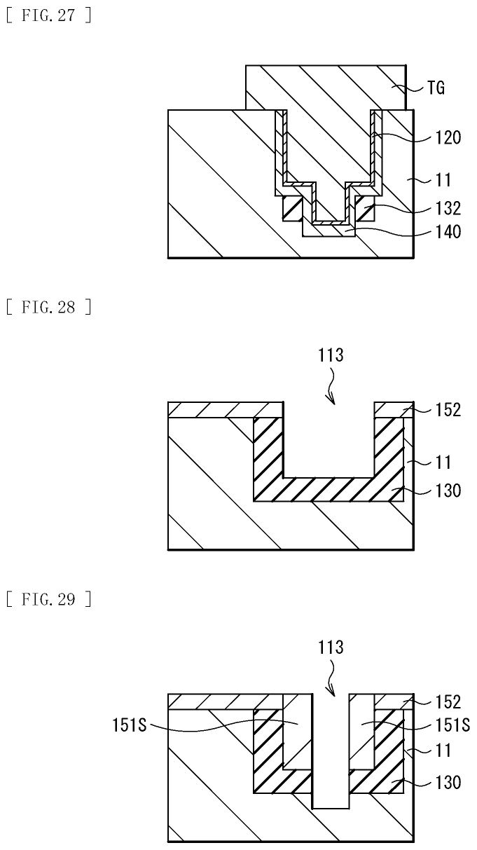

Thereafter, as illustrated in FIG. 27, the gate insulation film 120 and the transfer gate electrode TG are sequentially formed on the semiconductor substrate 11 inside the opening 113. Thus, it is possible to form the transfer transistor according to the second modification example. In the transfer transistor according to the second modification example, the first conduction-type region 132 is formed only on the lateral part of the second electrode section 112 and the under part of the first electrode section 111, and it is thus possible to increase the density gradient of the first conduction-type impurity in the depth direction of the semiconductor substrate 11. In addition, in the transfer transistor according to the second modification example, it is also possible to form the second conduction-type region 140 in a similar manner even in a case where a method other than the ion implantation is used.

### Third Modification Example

Referring to FIGS. 28 to 32, a method of forming a transfer transistor according to the third modification example will be described. FIGS. 28 to 32 are vertical cross-sectional views sequentially explaining processes of forming the transfer transistor according to the third modification example.

In the transfer transistor according to the third modification example, the first conduction-type region 130 and the second conduction-type region 140 are both formed by solid phase diffusion or plasma doping.

Specifically, as illustrated in FIG. 28, the patterning resist 152 is stacked on the surface of the semiconductor substrate 11, following which the opening 113 having a size corresponding to the first electrode section 111 is etched in the semiconductor substrate 11. Thereafter, the first conduction-type region 130 is formed uniformly on the surface of the semiconductor substrate 11 exposed by the opening 113, by solid phase diffusion or plasma doping. For example, in a case of using the solid phase diffusion, for example, a layer including the first conduction-type impurity is stacked on the surface of the semiconductor substrate 11 exposed by the opening 113, following which RTA is performed, thereby forming the first conduction-type region 130 on the surface of the semiconductor substrate 11. In a case of using the plasma doping, for example, a plasma is generated using gas including the first conduction-type impurity, following which a bias-voltage is applied to the semiconductor substrate 11, thereby forming the first conduction-type region 130 on the surface of the semiconductor substrate 11.

Thereafter, as illustrated in FIG. 29, the side-wall spacer 151S is formed inside the opening 113 to reduce the opening width of the opening 113, and the bottom surface inside the opening 113 is etched using the side-wall spacer 151S as a mask. Thus, the opening 113 is extended in the depth direction of the semiconductor substrate 11, thereby causing the semiconductor substrate 11 to have an opening corresponding to the second electrode section 112. In this case, the opening 113 is etched to a depth that separates the first conduction-type region 132 provided on the under part of the opening 113 in the preceding stage.

Thereafter, as illustrated in FIG. 30, the side-wall spacer 151S is removed to expose the semiconductor substrate 11 inside the opening 113.

Thereafter, the second conduction-type region 140 is formed uniformly on the surface of the semiconductor substrate 11 exposed by the opening 113, by solid phase diffusion or plasma doping. In a case of using the solid phase diffusion, for example, a layer including the second conduction-type impurity is stacked on the surface of the semiconductor substrate 11 exposed by the opening 113, following which RTA (is performed, thereby forming the second conduction-type region 140 on the surface of the semiconductor substrate 11. In a case of using the plasma doping, for example, a plasma is generated using gas including the second conduction-type impurity, following which a bias-voltage is applied to the semiconductor substrate 11, thereby forming the second conduction-type region 140 on the surface of the semiconductor substrate 11.

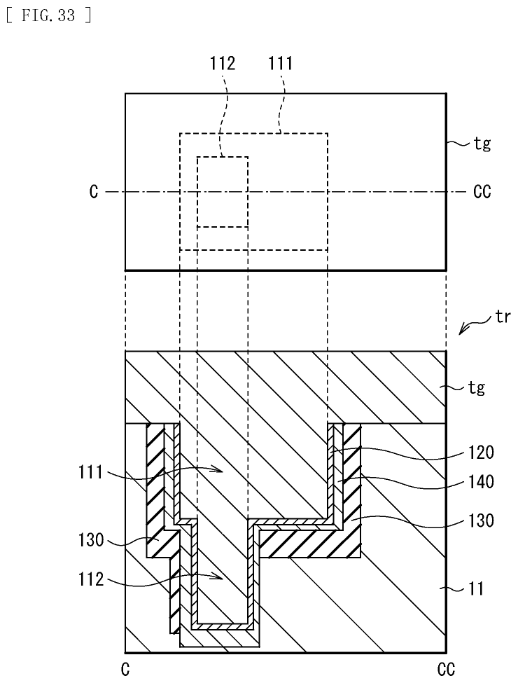

Thereafter, as illustrated in FIG. 32, the patterning resist 152 is removed, following which the gate insulation film 120 and the transfer gate electrode TG are sequentially formed on the semiconductor substrate 11 inside the opening 113. Thus, it is possible to form the transfer transistor according to the third modification example. In the transfer transistor according to the third modification example, it is possible to form the first conduction-type region 130 and the second conduction-type region 140 in a similar manner even in a case where a method other than the ion implantation is used.

### 2. SECOND EMBODIMENT

Hereinafter, referring to FIGS. 33 to 38, an imaging device according to a second embodiment of the present disclosure will be described. The imaging device according to the second embodiment differs from the transfer transistor according to the first embodiment in a structure of the transfer gate electrode. Accordingly, a description of an overall configuration of the imaging device will be omitted here.

### 2.1. Configuration of Transfer Transistor

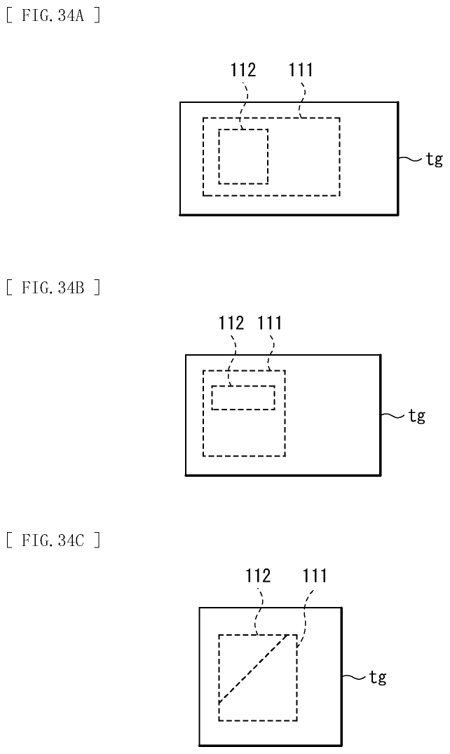

First, referring to FIGS. 33 to 34C, a vertical gate structure of a transfer transistor tr according to the present embodiment will be described in detail. FIG. 33 is a schematic plan view and a schematical vertical cross-sectional view of the vertical gate structure of the transfer transistor tr according to the present embodiment. The cross-sectional view of FIG. 33 is, for example, a cross-sectional view taken along a line C-CC in the plan view of FIG. 33.

As illustrated in FIG. 33, the transfer gate electrode tg according to the present embodiment includes the first electrode section 111 and the second electrode section 112, in a similar manner as the first embodiment. The transfer gate electrode tg according to the present embodiment differs from the transfer gate electrode TG according to first embodiment in that the center of the first electrode section 111 and the center of the second electrode section 112 do not coincide with each other and deviate from each other in one direction in the plane of the one principal surface of the semiconductor substrate 11.

In the transfer gate electrode TG according to the first embodiment, the positional relationship between the first electrode section 111 and the second electrode section 112 is controlled in a self-aligned manner by using the side-wall spacer 151S. Accordingly, in the transfer gate electrode TG according to the first embodiment, the center (or center of gravity) of the first electrode section 111 and the center (or center of gravity) of second electrode section 112 substantially coincide with each other. More specifically, in the transfer gate electrode TG according to the first embodiment, the planar shape of the second electrode section 112 has a similar shape in which the planar shape of the first electrode section 111 is reduced while the center of gravity is fixed.

In contrast, in the transfer gate electrode tg according to the second embodiment, the planar shapes of the first electrode section 111 and the second electrode section 112 and the positional relationship between the first electrode section 111 and the second electrode section 112 are appropriately controlled by using lithography and etching using separate masks. This makes it possible, in the transfer gate electrode tg according to the second embodiment, to extend the first conduction-type region 130 of the under part of the first electrode section 111 in any plane region.

For example, depending on a configuration of the pixel circuit, the photoelectric converter PD and the floating diffusion FD may be disposed separately not only in the depth direction of the semiconductor substrate 11 but also in an in-plane direction of the one principal surface of the semiconductor substrate 11. In such a case, it is desired to extend the first conduction-type region 130 not only in the depth direction of the semiconductor substrate 11 but also in the in-plane direction of the one principal surface of the semiconductor substrate 11. In the transfer gate electrode tg according to the present embodiment, it is possible to appropriately control the planar shapes of and the positional relationship between the first electrode section 111 and the second electrode section 112, which makes it possible to dispose the first conduction-type region 130 formed on the under part of the first electrode section 111 in any plane region.

Further, according to the present embodiment, it is possible to provide the transfer gate electrode tg in a three-dimensional form having different aspect ratios in different directions in the plane of the one principal surface of the semiconductor substrate 11. Specifically, as illustrated in the plan view of FIG. 33, the planar shape of the first electrode section 111 and the planar shape of the second electrode section 112 are dissimilar to each other, and this makes it possible to reduce the aspect ratio of the transfer gate electrode tg in one direction (the longitudinal direction of the first electrode section 111 in FIG. 33) in the plane of the one principal surface of the semiconductor substrate 11. According to this, it is possible to reduce a level of difficulty of processes of manufacturing the transfer transistor according to the present embodiment.

Next, referring to FIGS. 34A to 34C, variations of the planar shapes of the first electrode section 111 and the second electrode section 112 and the positional relationships between the first electrode section 111 and the second electrode section 112 according to the present embodiment will be described. FIGS. 34A to 34C are each a schematic plan view of a variation of: the planar shapes of the first electrode section 111 and the second electrode section 112; and the positional relationship between the first electrode section 111 and the second electrode section 112.

For example, as illustrated in FIG. 34A, the planar shape of the first electrode section 111 and the planar shape of the second electrode section 112 may be rectangular shapes that are dissimilar to each other. In this case, the planar shape of the second electrode section 112 is approximately half the planar shape of the first electrode section 111 and may be biased toward one longitudinal side of the first electrode section 111.

For example, as illustrated in FIG. 34B, the planar shape of the first electrode section 111 may be a square shape, and the planar shape of the second electrode section 112 may be a rectangular shape. In this case, the planar shape of the second electrode section 112 is approximately ⅓ of the planar shape of the first electrode section 111, and the second electrode section 112 may be disposed in the vicinity of a side in a predetermined direction of the first electrode section 111.

“For example, as illustrated in FIG. 34C, the planar shape of the first electrode section 111 may be a square shape, and the planar shape of the second electrode section 112 may be a right-angled triangular shape. In this case, the planar shape of the second electrode section 112 may be disposed to share one vertex and two sides with the planar shape of the first electrode section 111.

The planar shape of the first electrode section 111 and the planar shape of the second electrode section 112 may be a combination of any of circular shapes, elliptical shapes, and polygonal shapes of a pentagon or more.

The planar shape of the second electrode section 112 may also be disposed to be contained inside the planar shape of the first electrode section 111. Thus, in the transfer gate electrode tg according to the present embodiment, it is possible to provide the first conduction-type region 130 on the under part of the first electrode section 111 protruding from the planar shape on which the second electrode section 112 is formed.

Here, in order to form the first conduction-type region 130 that transfers the electric charge in the in-plane direction of the one principal surface of the semiconductor substrate 11 in a larger area, it is preferable that the first electrode section 111 be provided in such a manner as to have a larger planar area which is not overlapped with the second electrode section 112. Specifically, in a planar view of the one principal surface of the semiconductor substrate 11, it is preferable that the planar shapes and the placement of the first electrode section 111 and the second electrode section 112 are controlled in such a manner that a planar area in which the first electrode section 111 and the second electrode section 112 do not overlap with each other becomes larger than a planar area in which the first electrode section 111 and the second electrode section 112 overlap with each other.

### 2.2. Method of Forming Transfer Transistor

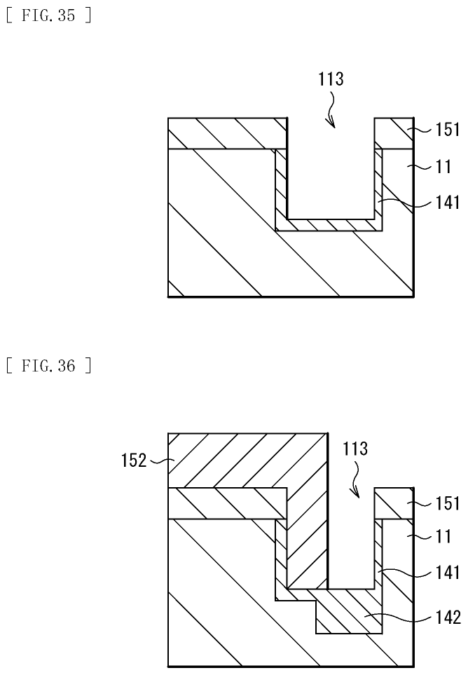

Next, with reference to FIGS. 35 to 38, a method of forming the transfer transistor tr according to the present embodiment will be described. FIGS. 35 are 38 are vertical cross-sectional views sequentially explaining processes of forming the transfer transistor tr according to the present embodiment.

First, as illustrated in FIG. 35, the hard mask 151 is stacked on the semiconductor substrate 11, and thereafter, the opening 113 having a size corresponding to the first electrode section 111 is etched in the semiconductor substrate 11. Thereafter, the second conduction-type impurity is ion-implanted into the opening 113 in the oblique direction to form the second conduction-type region 141 on the side surface and the bottom surface inside the opening 113.

Thereafter, as illustrated in FIG. 36, the patterning resist 152 in which a region in which the second electrode section 112 is to be formed is opened is stacked on the semiconductor substrate 11. Thereafter, the second conduction-type impurity is ion-implanted vertically into the bottom surface inside the opening 113 using the patterning resist 152 as a mask, to form the second conduction-type region 142 on the under part of the opening 113.

Thereafter, as illustrated in FIG. 37, the bottom surface inside the opening 113 is etched using the patterning resist 152 as a mask, to extend the opening 113 in the depth direction of the semiconductor substrate 11, thereby causing the semiconductor substrate 11 to have an opening corresponding to the second electrode section 112.

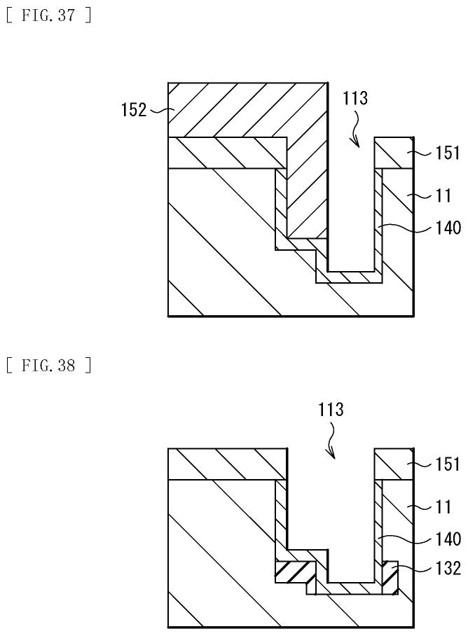

Thereafter, as illustrated in FIG. 38, the patterning resist 152 is removed to expose the semiconductor substrate 11 inside the opening 113. Thereafter, the first conduction-type impurity is ion-implanted into the opening 113 in the oblique direction to form the first conduction-type region 132 on the side surface in a deep portion and the bottom surface inside the opening 113. In addition, although not illustrated, the gate insulation film 120 and the transfer gate electrode TG are sequentially formed on the semiconductor substrate 11 inside the opening 113. Thus, it is possible to form the transfer transistor tr according to the present embodiment.

In the transfer transistor tr according to the present embodiment, the planar shapes of the first electrode section 111 and the second electrode section 112 and the positional relationship between the first electrode section 111 and the second electrode section 112 are appropriately controllable, which makes it possible to control more flexibly the region in which first conduction-type region 130 is to be formed.

### 3. APPLICATION EXAMPLES

### (Example of Application to Imaging System)

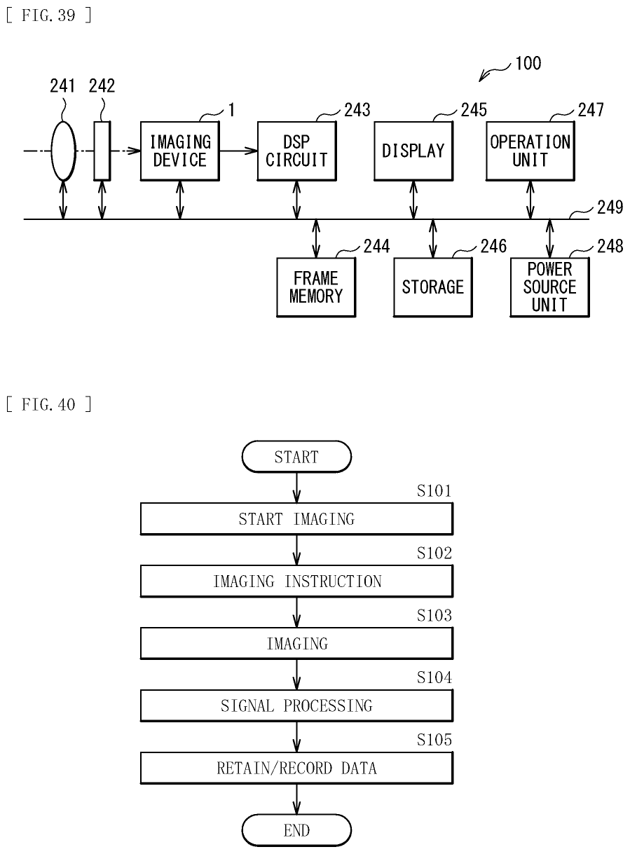

FIG. 39 illustrates an example of a schematic configuration of an imaging system 100 including the above-described imaging device 1 according to the above-described embodiments and modification examples.

The imaging system 100 is, for example, an electronic apparatus which is an imaging device such as a digital still camera or a video camera, a portable terminal device such as a smartphone or a tablet-type terminal, or the like. The imaging system 100 includes, for example, the imaging device 1 according to the above-described embodiments and modification examples, a DSP circuit 243, a frame memory 244, a display 245, a storage 246, an operation unit 247, and a power source unit 248. In the imaging system 100, the imaging device 1, the DSP circuit 243, the frame memory 244, the display 245, the storage 246, the operation unit 247, and the power source unit 248 are coupled to each other via a bus line 249.

The imaging device 1 outputs image data corresponding to incident light. The DSP circuit 243 is a signal processing circuit that processes a signal (i.e., image data) outputted from the imaging device 1. The frame memory 244 temporarily retains the image data processed by the DSP circuit 243 in units of frames. The display 245 includes, for example, a panel-type display device such as a liquid crystal panel or an organic EL (Electro Luminescence) panel, and displays a moving image or a still image captured by the imaging device 1. The storage 246 includes a recording medium such as a semi-conductor memory or a hard disk, and records the image data of the moving image or the still image captured by the imaging device 1 thereon. The operation unit 247 outputs operation commands for various functions of the imaging system 100 in accordance with user's operations. The power source unit 248 supplies various power sources to be operation power sources of the imaging device 1, the DSP circuit 243, the frame memory 244, the display 245, the storage 246, and the operation unit 247.

Next, imaging procedures in the imaging system 100 will be described.

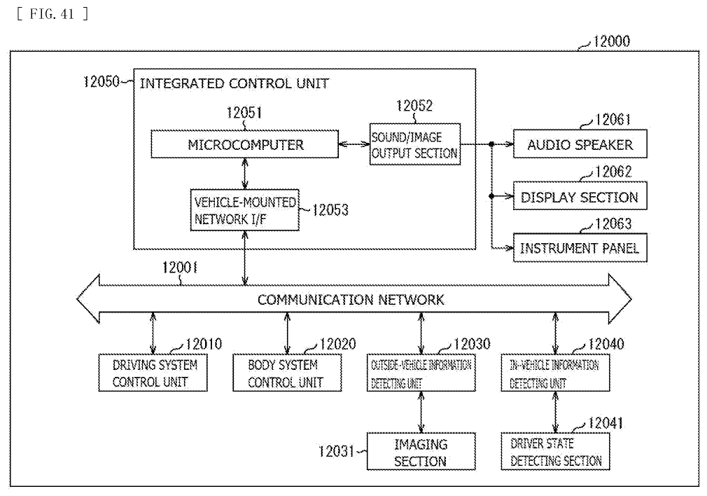

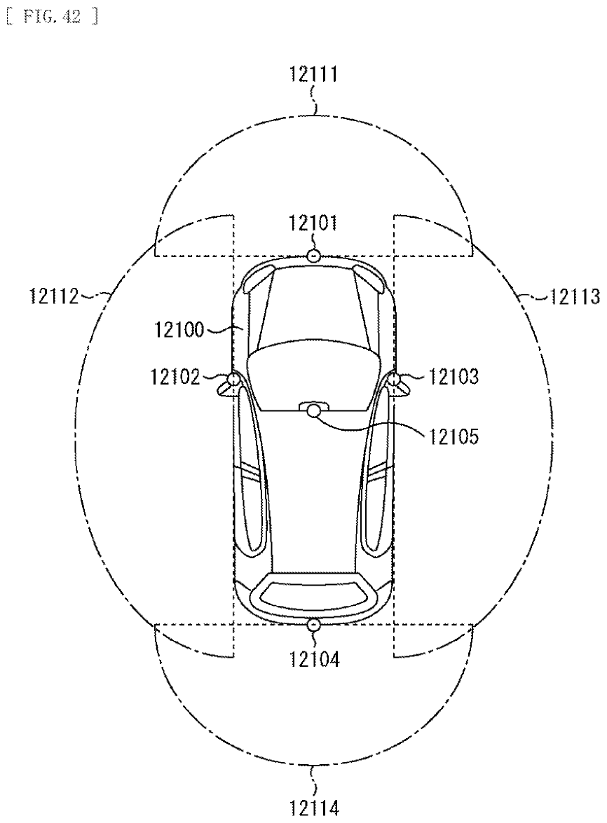

FIG. 40 illustrates an example of a flowchart of imaging operation in the imaging system 100. A user issues a command to start imaging by operating the operation unit 247 (S101). The operation unit 247 then transmits the imaging command to the imaging device 1 (S102). Upon receiving the imaging command, the imaging device 1 (specifically, a system control circuit 36) performs imaging by a predetermined imaging method (S103).

The imaging device 1 outputs the captured image data to the DSP circuit 243. Here, the image data is data of all pixels of pixel signals generated on the basis of charge temporarily retained in a floating diffusion FD. The DSP circuit 243 performs predetermined signal processing (e.g., noise-reducing processing) on the image data inputted from the imaging device 1 (step S104). The DSP circuit 243 causes the frame memory 244 to retain the image data on which the predetermined signal processing has been performed. Thereafter, the frame memory 244 causes the storage 246 to store the image data (S105). In this manner, imaging in the imaging system 100 is performed.

In the present application example, the imaging device 1 according to the above-described embodiments and the modification examples thereof is applied to the imaging system 100. According to the technology of the present disclosure, it is possible to further improve an image quality of an image captured by the imaging device 1 by increasing a transfer efficiency of the electric charge from the photoelectric converter PD to the floating diffusion FD. Therefore, according to the technology of the present disclosure, it is possible to provide the imaging system 100 that is able to capture an image of higher image quality.

### (Example of Application to Mobile Body Control System)

The technology according to the present disclosure (the present technology) is applicable to a variety of products. For example, the technology according to the present disclosure may be achieved as a device mounted on any type of mobile body such as a vehicle, an electric vehicle, a hybrid electric vehicle, a motorcycle, a bicycle, a personal mobility, an airplane, a drone, a vessel, or a robot.

FIG. 41 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 41, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 41, an audio speaker 12061, a display section 12062, and an instrument panel 12063 are illustrated as the output device. The display section 12062 may, for example, include at least one of an on-board display and a head-up display.

FIG. 42 is a diagram depicting an example of the installation position of the imaging section 12031.

In FIG. 42, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 42 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the forgoing, described is one example of the mobile body control system to which the technology according to the present disclosure is applicable. The technology according to the present disclosure is applicable to the imaging section 12031 of the above-described components. Specifically, the imaging device 1 according to the above-described embodiments and modification examples is applicable to the imaging section 12031. The technology of the present disclosure makes it possible to obtain a captured image of higher image quality, thereby making it possible to perform high-precision control using the captured image in the mobile body control system.

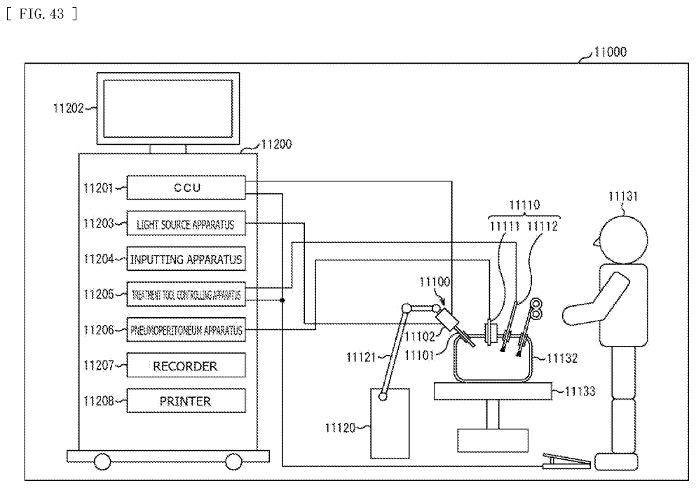

FIG. 43 is a view depicting an example of a schematic configuration of an endoscopic surgery system to which the technology according to an embodiment of the present disclosure (present technology) can be applied.

In FIG. 43, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endo scope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

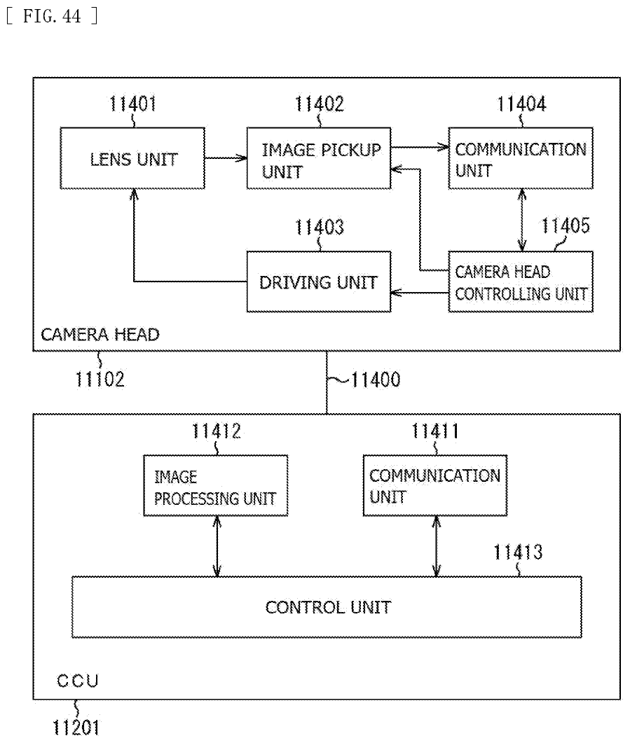

FIG. 44 is a block diagram depicting an example of a functional configuration of the camera head 11102 and the CCU 11201 depicted in FIG. 43.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The above has described the example of the endoscopic surgery system to which the technology according to the present disclosure may be applied. The technology according to the present disclosure may be preferably applied to the image pickup unit 11402 included in the camera head 11102 of the endoscope 11100 among the above-described components. The technology according to the present disclosure makes it possible to further improve an image quality of an image captured by the image pickup unit 11402, thereby making it possible to improve visibility and operability of the user using the endoscopic surgery system.

Although the description has been given with reference to the first and second embodiments and the modification examples, the present disclosure is not limited to the foregoing embodiments, etc., and may be modified in a variety of ways.

Further, not all of the configurations and operations described in the respective embodiments are indispensable as the configurations and operations of the present disclosure. For example, among the components in the respective embodiments, components not described in the independent claim indicating the most significant concepts of the present disclosure are to be understood as optional components.

Terms used throughout this specification and the appended claims should be construed as “non-limiting” terms. For example, a term “comprise” or “include” should not be construed as “being limited to those recited as included”. The term “have” should not be construed as “being limited to those recited as included”.

Terms used herein are used merely for convenience of description, and include those whose configuration and operation are not limited. For example, the terms “right”, “left”, “top” and “bottom” merely indicate the directions on the drawing to which is being referred. The terms “inner side” and “outer side” refer to a direction toward the center of the element of interest and a direction away from the center of the element of interest, respectively. The same applies to terms similar to these terms and terms having the similar meaning.

It is to be noted that the present technology may have the following configurations. According to the technology according to the present disclosure having the following configurations, it becomes possible to form more appropriately, in the desired region, the first conduction-type region to be the transfer path of the electric charge in the vertical gate structure. This makes it possible to provide an imaging device having a more optimized vertical gate structure. It is to be noted that the effects described herein are not necessarily limiting, and any of the effects described in the present disclosure may be provided.

(1)

An imaging device including:

a photoelectric converter that is provided on an inner side than one principal surface of a semiconductor substrate;

a transfer gate electrode that includes a first electrode section and a second electrode section, and provides as a transfer path which reads electric charge that has been photoelectrically converted by the photoelectric converter, the first electrode section extending, in a columnar shape, from the one principal surface of the semiconductor substrate in a depth direction of the semiconductor substrate, the second electrode section further extending, in a columnar shape, from the first electrode section in the depth direction; and

a first conduction-type region that includes a first conduction-type impurity and is provided on a lateral part of the transfer gate electrode, in which

a width of the second electrode section in at least one direction in a plane of the one principal surface is smaller than a width of the first electrode section in the at least one direction, and

the first conduction-type region is provided at least in a region of an under part of the first electrode section and a lateral part of the second electrode section, in the at least one direction.

(2)

The imaging device according to (1), in which the first conduction-type region is further extended along an outer shape in the at least one direction of the transfer gate electrode.

(3)

The imaging device according to (2), in which the first conduction-type region is bent in the depth direction.

(4)

The imaging device according to (3), in which the first conduction-type region is provided continuously along the lateral part of the second electrode section, the under part of the first electrode section protruding from the second electrode section, and a lateral part of the first electrode section.

(5)

The imaging device according to (4), in which an impurity concentration in the first conduction-type region provided on the lateral part of the first electrode section is different from an impurity concentration in the first conduction-type region provided on the lateral part of the second electrode section.

(6)

The imaging device according to any one of (1) to (5), further including

a second conduction-type region that is provided on the semiconductor substrate opposed to the first electrode section and the second electrode section, the second conduction-type region including a second conduction-type impurity.

(7)

The imaging device according to (6), in which the second conduction-type region is provided continuously along an under part of the second electrode section, the lateral part of the second electrode section, the under part of the first electrode section protruding from the second electrode section, and a lateral part of the first electrode section.

(8)

The imaging device according to (7), in which the second conduction-type region is provided between: the first conduction-type region; and the first electrode section and the second electrode section.

(9)

The imaging device according to any one of (1) to (8), in which, in a planar view of the one principal surface of the semiconductor substrate, a region in which the second electrode section is formed is included in a region in which the first electrode section is formed.

(10)

The imaging device according to any one of (1) to (9), in which, in a planar view of the one principal surface of the semiconductor substrate, a shape of a region in which the second electrode section is formed is similar to a shape of a region in which the first electrode section is formed.

(11)

The imaging device according to (10), in which, in a planar view of the one principal surface of the semiconductor substrate, a center of gravity of the region in which the second electrode section is formed substantially coincides with a center of gravity of the region in which the first electrode section is formed.

(12)

The imaging device according to any one of (1) to (9), in which, in a planar view of the one principal surface of the semiconductor substrate, a shape of a region in which the second electrode section is formed is dissimilar to a shape of a region in which the first electrode section is formed.

(13)

The imaging device according to any one of (1) to (12), in which, in a planar view of the one principal surface of the semiconductor substrate, an area of a region in which the first electrode section is formed that is not overlapped with a region in which the second electrode section is formed is larger than an area of the region in which the first electrode section is formed that is overlapped with the region in which the second electrode section is formed.

(14)

The imaging device according to (13), in which, in a planar view of the one principal surface of the semiconductor substrate, the first conduction-type region is provided on an under part of the region in which the first electrode section is formed that is not overlapped with the region in which the second electrode section is formed.

(15)

The imaging device according to any one of (1) to (14), in which,

where a length of the the first electrode section in the depth direction of the semiconductor substrate is represented by b, a length of the the second electrode section in the depth direction is represented by c, and a width of the first electrode section in the at least one direction is represented by d,

a shape of the transfer gate electrode satisfies, in the at least one direction, 0<b<3.5d, 0<c<3.5d, and b+c<6d.

(16)

The imaging device according to (15), in which the shape of the transfer gate electrode satisfies, in at least one direction in the plane of the one principal surface, b+c<2d.

(17)

The imaging device according to any one of (1) to (16), in which the transfer gate electrode is provided inside an opening that the semiconductor substrate has with a gate insulation film interposed therebetween.

(18)

The imaging device according to any one of (1) to (17), in which the transfer path transfers the electric charge that has been photoelectrically converted by the photoelectric converter to a floating diffusion provided on the one principal surface of the semiconductor substrate.

This application claims the benefit of Japanese Priority Patent Application JP2019-133347 filed with the Japan Patent Office on Jul. 19, 2019, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An imaging device comprising:
a photoelectric converter that is provided on an inner side than one principal surface of a semiconductor substrate;
a transfer gate electrode that includes a first electrode section and a second electrode section, and provides as a transfer path which reads electric charge that has been photoelectrically converted by the photoelectric converter, the first electrode section extending, in a columnar shape, from the one principal surface of the semiconductor substrate in a depth direction of the semiconductor substrate, the second electrode section further extending, in a columnar shape, from the first electrode section in the depth direction; and
a first conduction-type region that includes a first conduction-type impurity and is provided on a lateral part of the transfer gate electrode, wherein
a width of the second electrode section in at least one direction in a plane of the one principal surface is smaller than a width of the first electrode section in the at least one direction, and
the first conduction-type region is provided at least in a region of an under part of the first electrode section and a lateral part of the second electrode section, in the at least one direction.

2. The imaging device according to claim 1, wherein the first conduction-type region is further extended along an outer shape in the at least one direction of the transfer gate electrode.

3. The imaging device according to claim 2, wherein the first conduction-type region is bent in the depth direction.

4. The imaging device according to claim 3, wherein the first conduction-type region is provided continuously along the lateral part of the second electrode section, the under part of the first electrode section protruding from the second electrode section, and a lateral part of the first electrode section.

5. The imaging device according to claim 4, wherein an impurity concentration in the first conduction-type region provided on the lateral part of the first electrode section is different from an impurity concentration in the first conduction-type region provided on the lateral part of the second electrode section.

6. The imaging device according to claim 1, further comprising
a second conduction-type region that is provided on the semiconductor substrate opposed to the first electrode section and the second electrode section, the second conduction-type region including a second conduction-type impurity.

7. The imaging device according to claim 6, wherein the second conduction-type region is provided continuously along an under part of the second electrode section, the lateral part of the second electrode section, the under part of the first electrode section protruding from the second electrode section, and a lateral part of the first electrode section.

8. The imaging device according to claim 7, wherein the second conduction-type region is provided between: the first conduction-type region; and the first electrode section and the second electrode section.

9. The imaging device according to claim 1, wherein, in a planar view of the one principal surface of the semiconductor substrate, a region in which the second electrode section is formed is included in a region in which the first electrode section is formed.

10. The imaging device according to claim 1, wherein, in a planar view of the one principal surface of the semiconductor substrate, a shape of a region in which the second electrode section is formed is similar to a shape of a region in which the first electrode section is formed.

11. The imaging device according to claim 10, wherein, in a planar view of the one principal surface of the semiconductor substrate, a center of gravity of the region in which the second electrode section is formed substantially coincides with a center of gravity of the region in which the first electrode section is formed.

12. The imaging device according to claim 1, wherein, in a planar view of the one principal surface of the semiconductor substrate, a shape of a region in which the second electrode section is formed is dissimilar to a shape of a region in which the first electrode section is formed.

13. The imaging device according to claim 1, wherein, in a planar view of the one principal surface of the semiconductor substrate, an area of a region in which the first electrode section is formed that is not overlapped with a region in which the second electrode section is formed is larger than an area of the region in which the first electrode section is formed that is overlapped with the region in which the second electrode section is formed.

14. The imaging device according to claim 13, wherein, in a planar view of the one principal surface of the semiconductor substrate, the first conduction-type region is provided on an under part of the region in which the first electrode section is formed that is not overlapped with the region in which the second electrode section is formed.

15. The imaging device according to claim 1, wherein,
where a length of the the first electrode section in the depth direction of the semiconductor substrate is represented by b, a length of the the second electrode section in the depth direction is represented by c, and a width of the first electrode section in the at least one direction is represented by d,
a shape of the transfer gate electrode satisfies, in at least one direction in the plane of the one principal surface, 0<b<3.5d, 0<c<3.5d, and b+c<6d.

16. The imaging device according to claim 15, wherein the shape of the transfer gate electrode satisfies, in the at least one direction, b+c<2d.

17. The imaging device according to claim 1, wherein the transfer gate electrode is provided inside an opening that the semiconductor substrate has with a gate insulation film interposed therebetween.

18. The imaging device according to claim 1, wherein the transfer path transfers the electric charge that has been photoelectrically converted by the photoelectric converter to a floating diffusion provided on the one principal surface of the semiconductor substrate.
